(19) United States
(12) Patent Application Publication
(10) Pub. No.: US 2019/0006777 A1
(43) Pub. Date: Jan. 3, 2019

(54) Printed Circuit Board Solder Joints

(71) Applicant: Lutron Electronics Co., Inc., Coopersburg, PA (US)

(72) Inventors: Matthew Knauss, Somerville, MA (US); Roland L. Ledyard, Bethlehem, PA (US)

(73) Assignee: Lutron Electronics Co., Inc., Coopersburg, PA (US)

(21) Appl. No.: 16/023,738

(22) Filed: Jun. 29, 2018

Related U.S. Application Data
(60) Provisional application No. 62/527,554, filed on Jun. 30, 2017.

(51) Int. Cl. H01R 12/52; H01R 43/02; H05K 1/11; H05K 1/14; H05K 1/18; H05K 3/18; H05K 3/36; H05K 3/40; H05K 3/42

(52) U.S. Cl. CPC H01R 12/523; H01R 43/0256; H05K 1/115; H05K 1/141; H05K 1/181; H05K 3/18; H05K 3/005; H05K 3/403; H05K 3/42; H05K 1/117; H05K 2201/048; H05K 2201/09163; H05K 2201/09072; H05K 3/366

(57) ABSTRACT

A printed circuit board (PCB) assembly may include a motherboard PCB with one or more plated holes and a daughterboard PCB with one or more plated fingers extending from a lower edge of the daughterboard PCB. The plated fingers may have a rectangular and/or square cross section. The plated fingers may be plated on four sides that define the rectangular cross section. Each of the plated holes may be configured to receive a respective plated finger, for example, such that a lower portion of the plated fingers extend beyond a lower surface of the motherboard PCB. Each of the plated holes may be configured to be electrically connected to a respective plated finger via a solder joint. The solder joint may extend around the respective plated finger. The solder joints for the plated fingers may be configured to secure the daughterboard PCB to the motherboard PCB.

### CROSS-REFERENCE TO RELATED APPLICATIONS

This application claims priority to Provisional U.S. Patent Application No. 62/527,554, filed Jun. 30, 2017, the entire disclosure of which is incorporated by reference herein.

### BACKGROUND

Motherboard and daughterboard printed circuit board (PCB) assemblies are well known for many electrical device applications. Various connectors may be used to join the boards together, such as bent angle connectors, which may be surface mount or through-hole connectors, flexible cables, and the like. However, connectors take up valuable board space. Therefore, a reliable assembly for motherboard and daughterboards is needed which minimizes the amount of board space used for the joining connection.

### SUMMARY

As described herein, a printed circuit board (PCB) assembly may include a motherboard PCB and a daughterboard PCB. The motherboard PCB may include one or more plated holes. The plated holes may have plating on an inside surface. The plating on the plated holes may extend onto an upper surface and/or a lower surface of the motherboard PCB. The daughterboard PCB may include one or more plated fingers extending from a lower edge of the daughterboard PCB. The plated fingers may be routed from the lower edge of the daughterboard PCB. The plated fingers may have a rectangular and/or square cross section. The plated fingers may be plated on four sides that define the rectangular cross section. A lower surface of the plated fingers may also be plated.

Each of the plated holes may be configured to receive a respective plated finger, for example, such that a lower portion of the plated fingers extend beyond a lower surface of the motherboard PCB. Each of the plated holes may be configured to be electrically connected to a respective plated finger via a solder joint. The solder joint may extend around the respective plated finger. For example, the solder joint may extend 360 degrees around the respective plated finger. The solder joint may extend above and/or below upper and/or lower surfaces the motherboard PCB. The solder joint may include fountain selective solder (FSS), wave solder, selective solder, hand solder, and/or the like. The solder joints for the plated fingers may be configured to secure the daughterboard PCB to the motherboard PCB.

The daughterboard PCB may define a tab. The motherboard PCB may define a slot. The tab may be configured to be received by the slot. The tab and the slot may be configured to prevent lean of the daughterboard PCB with respect to the motherboard PCB, that is, to maintain the daughterboard PCB perpendicular to the motherboard PCB.

The above advantages and features are of representative embodiments only. They are not to be considered limitations. Additional features and advantages of embodiments will become apparent in the following description, from the drawings, and from the claims.

### BRIEF DESCRIPTION OF THE DRAWINGS

FIGS. 1A and 1B are an exploded view of an example printed circuit board (PCB) assembly having a motherboard PCB and a daughterboard PCB.

FIG. 2 is an exploded view of an example printed circuit board (PCB) assembly having a motherboard PCB and a daughterboard PCB.

FIG. 3 is a side view of an example daughterboard PCB having plated fingers.

FIG. 4 is a cross section view of an example PCB assembly having a motherboard PCB and a daughterboard PCB.

FIG. 5 is a bottom view of another example PCB assembly.

FIG. 6 is a method for creating a daughterboard PCB according to an example embodiment.

### DETAILED DESCRIPTION

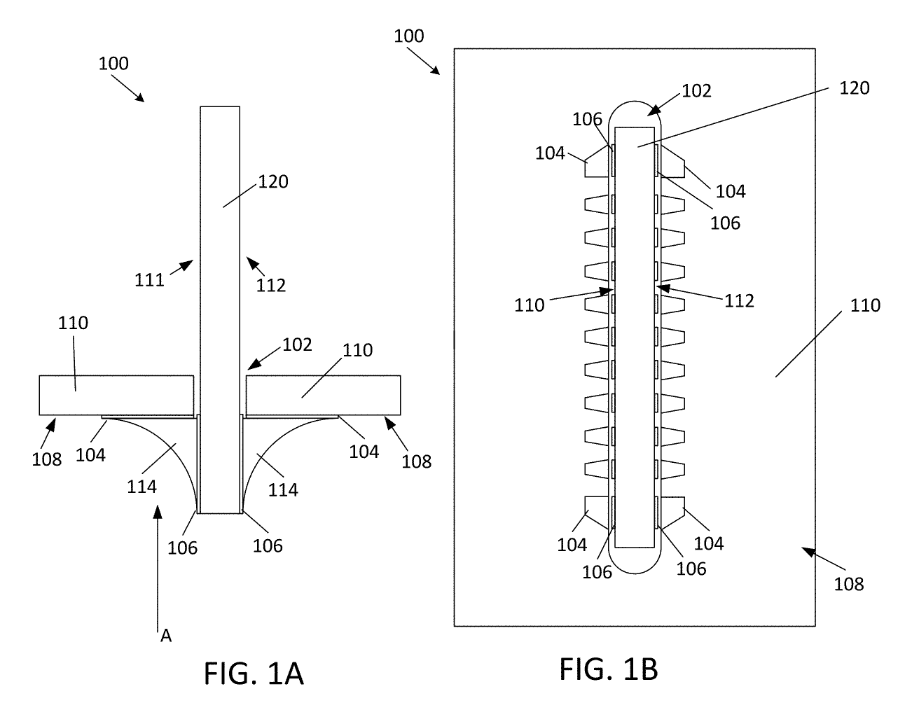

Referring to FIGS. 1A and 1B there is shown an example printed circuit board (PCB) assembly 100. Assembly 100 includes a motherboard (PCB) 110 connected to a daughterboard PCB 120. FIG. 1A shows a side view of assembly 100 and FIG. 1B shows a bottom view of assembly 100 (i.e., the view along direction A of FIG. 1A). (One will recognize that while a motherboard PCB and daughterboard PCB are described herein as the motherboard PCB having one or more openings/slots/holes that receive the daughterboard PCB, the daughterboard PCB may alternatively have one or more openings/slots/holes that receive the motherboard PCB. Similarly, the connection of a motherboard PCB and daughterboard PCB as described herein may be applied to any first and second PCBs, for example). Each board shown in FIGS. 1A and 1B may include one or more circuits, electrical components, etc. (not shown). Such a motherboard PCB/daughterboard PCB combination as shown in the figures may be used in a load control device such as a lighting ballast or light-emitting diode (LED) driver, for example, although one will recognize this configuration may also be applicable to other types of electrical devices, and may be used in applications other than lighting control.

The motherboard PCB 110 may have a slot 102 that receives the daughterboard PCB 120. The motherboard PCB may have one or more plated pads 104 on its bottom side or surface 108 (the terms side and surface may be used interchangeably herein), for example. The daughterboard PCB may have one or more plated pads 106 on its front side or surface 111 and back surface 112, for example (One will recognize that terms such as bottom, lower, top, upper, front, back, rear, etc. are used herein as relative terms to assist in describing different sides or surfaces of PCBs; and for a PCB having two opposing sides or surfaces, for example, either surface can be viewed as the upper surface, for example, with the other opposing surface being viewed as the lower surface, or vis versa. Similarly, either surface can be viewed as the rear surface, for example, with the other opposing surface being viewed as the front surface, or vis versa, etc.). Solder may be applied to the pad(s) 106 of the daughterboard PCB and to the pad(s) 104 of the motherboard PCB to create one or more solder joint(s) 114 (not shown in FIG. 1B). The solder joints may create an electrical connection(s) between the plated pads 106 of the daughterboard PCB and the plated pads 104 of the motherboard PCB (e.g., to connect electrical components of the motherboard PCB to electrical components of the daughterboard PCB). The solder joints may also structurally connect the daughterboard PCB and the motherboard PCB. One possible issue with the solder joints 114 is that they may result in premature failure due to one or more of the following: thermal cycling, which may result in fatigue failure; assembly tolerances that result in a larger solder joint on one side of the daughterboard PCB; misalignment of plated pads 104 and 106; and/or other configuration weaknesses.

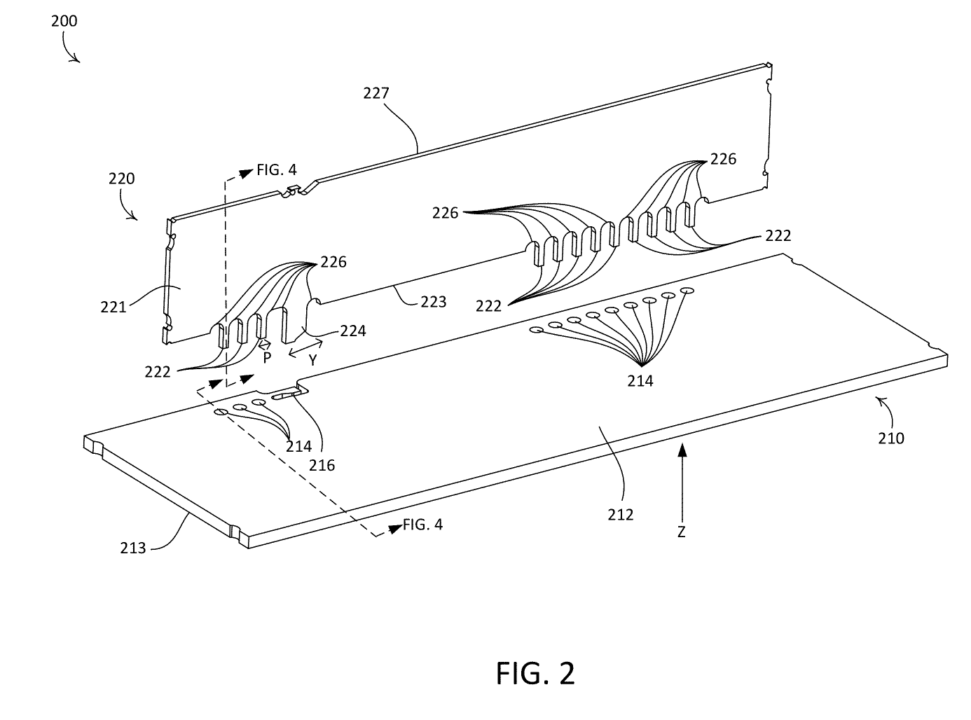

Referring now to FIG. 2, there is shown an exploded view of another example printed circuit board (PCB) assembly 200. The example PCB assembly 200 may be configured for a control device such as a lighting ballast or LED driver, although it may also be applicable to other types of electrical devices and to applications other than lighting applications. (Again, one will recognize that while a motherboard PCB and daughterboard PCB are described herein as the motherboard PCB having one or more openings/slots/holes that receive the daughterboard PCB, the daughterboard PCB may alternatively have one or more openings/slots/holes that receive the motherboard PCB. Similarly, the connection of a motherboard PCB and daughterboard PCB as described herein may be applied to any first and second PCBs, for example). The example PCB assembly 200 may include a motherboard PCB 210 and a daughterboard PCB 220. The motherboard PCB 210 may be configured to receive the daughterboard PCB 220. The motherboard PCB 210 may define a plurality of spaced apart holes or openings 214 therethrough. For example, the holes 214 may extend through the motherboard PCB 210 from an upper side or surface 212 of the motherboard PCB 210 to a lower opposing side or surface 213 of the motherboard PCB 210. The holes 214 may be linearly aligned with one another on the motherboard PCB 210. Each of the holes 214 may be similarly configured (e.g. same shape and size), although one will recognize that one or more of the holes may not be similarly configured. The motherboard PCB 210 may also define one or more slots 216, although slot 216 is not required. For example, the slot 216 may extend through the motherboard PCB 210 from the upper surface 212 of the motherboard PCB 210 to the lower opposing surface 213 of the motherboard PCB 210. The holes 214 may be linearly aligned with one another on the motherboard PCB 210. The slot 216 may be linearly aligned with the holes 214.

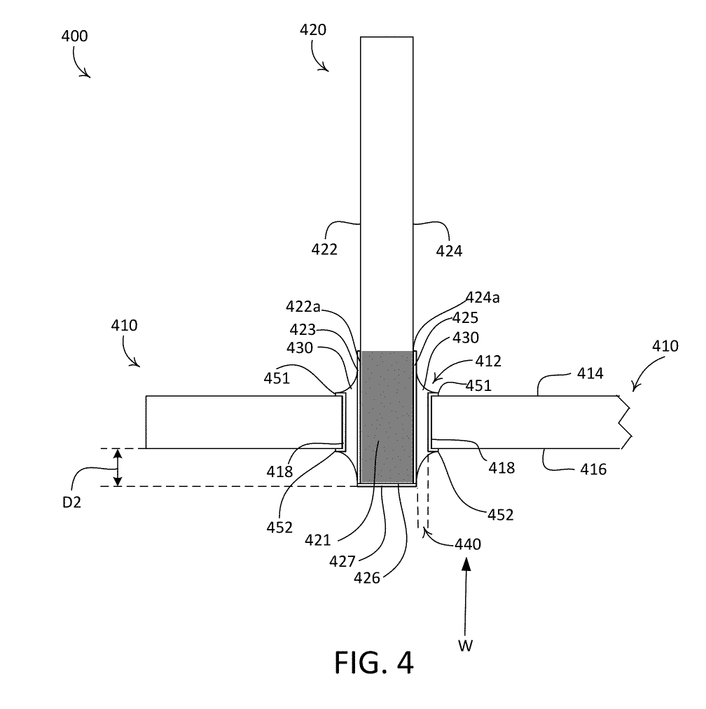

The daughterboard PCB may define a front side or surface 221 and an opposing rear side or surface 227 (e.g., similar to sides 422 and 424 as shown in FIG. 4). The daughterboard PCB may define a lower edge or surface 223 (e.g., an edge or surface that is perpendicular to surfaces 221 and 227). The lower edge 223 of the daughterboard PCB 220 may be configured to engage and/or be proximate to and/or be adjacent to the upper surface 212 of the motherboard PCB 210 (as shown, for example, in FIG. 4). For example, the lower edge 223 may be configured to rest on the upper surface 212 when the motherboard PCB 210 receives the daughterboard PCB 220. The daughterboard PCB 220 may define one or more spaced apart fingers 222. Each of the fingers 222 may be similarly configured (e.g. same shape, size, left-to-right length P, and vertical height), although one will recognize that one or more of the fingers may not be similarly configured. The fingers 222 may extend from the lower edge 223 of the daughterboard PCB 220. The fingers 222 may be configured to engage the holes 214 of the motherboard PCB 210. For example, each of the holes 214 may be configured to receive a respective finger of the fingers 222. Accordingly, there may be an equal number of fingers 222 as there are holes 214, although one will recognize that there may be more holes 214 than fingers 222, for example.

The daughterboard PCB 220 may include one or more tabs 224 that extend from the lower edge 223, although tab 224 is not required. The tab 224 may be routed from a lower portion of the daughterboard PCB 220. For example, the tab 224 may be defined by removing material from the lower portion of the daughterboard PCB 220. The tab 224 may be configured to engage the slot 216 of the motherboard PCB 210. For example, the slot 216 may be configured to receive the tab 224. Accordingly, there may be an equal number of tabs 224 as there are slots 216, although one will recognize that there may be more slots 216 than tabs 224, for example. The tab 224 may be configured to have an elongated length Y (where length Y is the length that runs parallel with edge 223, for example) and may be configured with the slot 216 (which may have a length configured to receive tab 224, such as a length slightly larger than length Y) to prevent lean of the daughterboard PCB 220 with respect to the motherboard PCB 210. The length Y of tab 224 may be longer than a length P of fingers 222, where length P may be the length that runs parallel with edge 223 for example. Slot 216 may similarly have a length that is larger/longer than a length or diameter of a hole 214. As an example, the slot 216 and the tab 224 may be configured to limit the skew of the daughterboard PCB 220 with respect to the motherboard PCB 210 (e.g., before and/or after solder is applied to the fingers 222 and holes 214). In other words, the motherboard PCB and daughterboard PCB, when connected, may be at a right angle or approximately at a right angle to each other (i.e., 90 degrees or approximately 90 degrees to each other, or perpendicular or approximately perpendicular degrees to each other). The slot 216 and tab 224 may assist in preventing lean or skew of the daughterboard PCB 220 with respect to the motherboard PCB 210 and thus keeping the two boards at a right angle. One will recognize that the finger/hole/tab/slot pattern shown in FIG. 2 and the number of fingers/holes/tabs/slots, etc. is merely an example intended for illustrative purposes only, and that any number of fingers/holes/tabs/slots may be used.

The daughterboard PCB 220 may also define concave sections or areas 226 on either and/or both sides of one or more of the fingers 222 (such as between adjacent fingers) and/or one or more of the fingers 222 and the tab 224 (such as between the tab and a finger adjacent to the tab). The concave sections 226 may be routed or punched sections of the lower edge 223 of the daughterboard PCB 220. For example, the concave sections 226 may be defined by routing material away from the lower edge 223 of the daughterboard PCB 220. Alternatively, the material may be removed through a punching process. In other words, each section 226 may be formed by removing a portion of the edge that lies between adjacent fingers, for example. The concave sections 226 may be configured to enable electrical separation of adjacent fingers 222 as discussed herein. For example, routing or punching the concave sections 226 may remove any excess plating from the lower edge 223 of the daughterboard PCB 220. While sections 226 are described herein as having a concave or arc-like or curved shape, one will recognize that sections 226 may have a different shape, and each of sections 226 may have a different shape, for example.

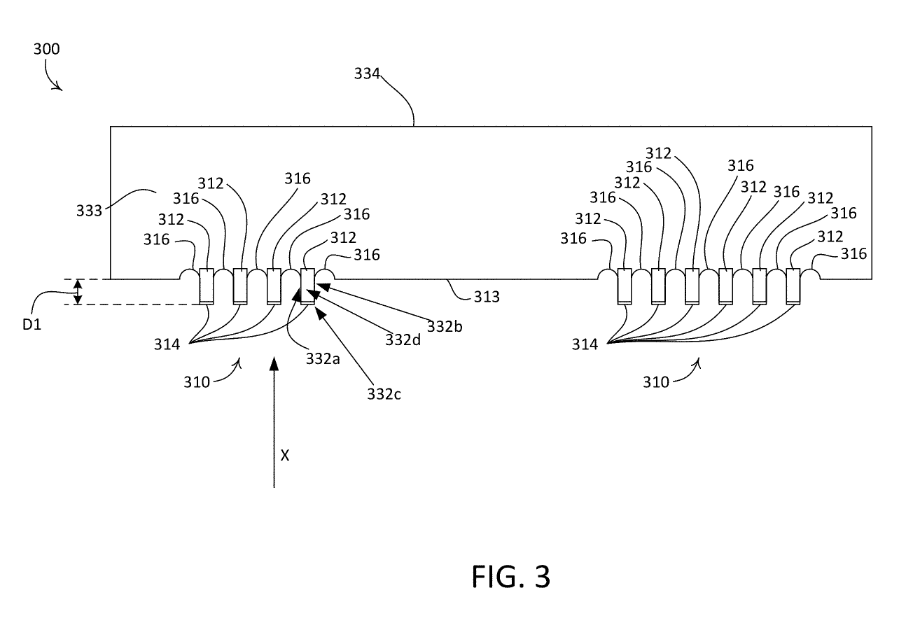

FIG. 3 is a side view of an example daughterboard PCB 300 (e.g., such as the daughterboard PCB 220 shown in FIG. 2). The daughterboard PCB 300 may have a front side or surface 333, a rear opposing side or surface 334, and may define a lower edge 313 (i.e., a surface that is perpendicular to surfaces 333 and 334). The daughterboard PCB 300 may define a plurality of plated fingers 310 (which may be similar to fingers 222). Although not shown, daughterboard PCB 300 may also include one or more tabs similar to tab 224. The plated fingers 310 may extend from the lower edge 313 of the daughterboard PCB 300 by a distance or height Dl. The distance D1 may be determined such that the plated fingers 310 can extend into and through the holes or openings of a motherboard PCB (e.g., such as the holes 214 of motherboard PCB 210 shown in FIG. 2) and/or such that the lower edge 313 may engage an upper surface of the motherboard PCB (e.g., such as surface 212 of motherboard PCB 210 shown in FIG. 2). The distance D1 may be configured such that the plated fingers 310 extend far enough through the holes or openings of the motherboard PCB (e.g., holes 214 of motherboard PCB 210) so that a solder joint can be applied to a gap between the plated fingers 310 and corresponding holes in the motherboard PCB as further discussed with respect to FIG. 4.

Each of the plated fingers 310 may have a rectangular and/or square cross section, for example along the lower surface 332c (i.e., surface 332c is the surface seen when viewing the fingers along direction X) (although other shaped cross sections are possible). For example, each of the plated fingers 310 may include four sides or surfaces that define the rectangular and/or square cross section (e.g., the four surfaces may include surface 332d that is along the front side or surface 333 of the daughterboard PCB 300, the opposing surface to surface 332d (not shown) that is along the rear side or surface 334 of the daughterboard PCB 300, and the two opposing inside surfaces 332a and 332b that are perpendicular to the front surface 333 and the rear surface 334/are perpendicular to the surface 332d as shown for one of the fingers in FIG. 3). The plated fingers 310 may contain a plating 312 on one or more of the four sides/surfaces (i.e., surface 332a, surface 332b, surface 332d, and the opposing surface to surface 332d) that define the rectangular and/or square cross section along surface 332c. The plated fingers 310 may also have plating 314 on the lower surface 332c (i.e., again, the surface 332c is viewed from direction X) of each respective plated finger of the plated fingers 310. One will recognize that not all fingers 310 need to be plated the same. For example, some fingers may not have plating on all five sides/surfaces, while other fingers may have plating on all five sides/surfaces, as described.

The daughterboard PCB 300 may define concave sections 316 (which may be similar to sections 226) on either and/or both sides 332a and 332b of the plated fingers 310. One will recognize that concave sections 316 may have shapes other than concave, and further, all sections need not be the same shape. The concave sections 316 may be routed or punched sections of the lower edge 313 of the daughterboard PCB 300. For example, the concave sections 316 may be defined by routing or punching material away from the lower edge 313 of the daughterboard PCB 300. The concave sections 316 may be configured to enable electrical separation of the plated fingers 310. For example, routing or punching the concave sections 316 may remove any excess plating from the lower edge 313 of the daughterboard PCB 300, thereby separating plating 312 between adjacent fingers. If daughterboard PCB 300 includes a tab similar to tab 124, it may or may not be similarly plated as fingers 310.

The daughterboard PCB 300 may be assembled and/or manufactured as described herein. After completion of the normal etching process of a copper-clad laminate to create circuit board traces, the daughterboard may go through a routing and/or drilling process. As part of the routing and/or drilling process, the fingers 310 may be created. The fingers 310 may or may not have copper plating on the front 332d and opposing rear surfaces leftover from the copper-clad laminate. The routing and drilling process may also create the individual boards on a PCB panel and may add drill holes for vias, which may be done at this time or at a later step in the process.

The plurality of plated fingers 310 may have a rectangular and/or square cross section. Routing the plurality of plated fingers 310 may create inside surfaces (i.e., the two surfaces 332a and 332b) that are unplated. Again, these inside surfaces may be perpendicular to front surface 333 and rear surface 334 of the daughterboard PCB 300. Next, the daughterboard 300 may go through a plating process to plate the fingers 310 (Again, surface 332d and the rear surface opposing surface 332d of a finger may be plated at this time if not already plated). The fingers may be plated such that each of the plurality of fingers 310 has plating 312 on the four surfaces (including surfaces 332a-b, 332d, and the rear surface opposing surface 332d), and plating 314 on a lower surface 332c of the respective finger. The plating 312 and/or 314 may be configured to receive solder as described herein.

During this process, when surfaces 332a and 332b are plated with plating 312, the exposed surfaces between the fingers 310 may also be plated, thereby electrically connecting the plated fingers. To electrically disconnect the fingers, the daughterboard PCB 300 may next be routed or punched in between the plurality of plated fingers 310 and/or on either side of the fingers 310. Routing or punching the daughterboard PCB 300 between the plated fingers 310 may include removing material from between respective/adjacent plated fingers 310 to create concave sections 316 and thus electrically disconnect the fingers. For example, the lower edge 313 of the daughterboard PCB 300 may be routed on either side of the plated fingers 310 to create the concave sections 316. Again, the concave sections may be configured or formed to enable electrical separation between the plating 312 of the plated fingers 310. The routing may also create the individual PCBs at this time, if this was not yet done in a previous step. This process is one example and other variations are possible.

FIG. 4 is a cross section view of an example PCB assembly 400 having a motherboard PCB 410 and a daughterboard PCB 420. As an example, assuming the motherboard PCB 210 and a daughterboard PCB 220 of FIG. 2 are plated and connected, FIG. 4 may be the cross-sectional view as shown in FIG. 2 (i.e., motherboard PCB 410 may correspond to motherboard PCB 210, daughterboard PCB 420 may correspond to daughterboard PCB 220, finger 421 may correspond to finger 222, and hole 412 may correspond to a hole 214). The daughterboard PCB 420 may define a first side or surface 422. The first surface 422 may be a rear surface of the daughterboard PCB 420. The daughterboard PCB 420 may define a second side or surface 424. The second surface 424 may be a front surface of the daughterboard PCB 420 that is opposing to the rear surface 422. The motherboard PCB 410 may define a first side or surface 414 (e.g., an upper surface) and a second opposing side or surface 416 (e.g., a lower opposing surface).

The daughterboard PCB 420 may include one or more fingers, including a finger 421 (as shown by the shaded area). For example, the daughterboard PCB 420 may define a plurality of fingers that includes the finger 421. The finger 421 may be plated. The finger 421 may include plating 423 on a first surface 422a of the finger. The finger 421 may include plating 425 on a second surface 424a. The finger 421 may include plating 427 on a lower surface 426 of the finger 421. The plating 427 may cover the lower surface 426 of the finger 421. For example, the plating 427 may extend from the plating 423 on the first surface 422 to the plating 425 on the second surface 424. The plating 427 may electrically connect plating 423 with plating 425. One will recognize that plating 427 may not be necessary/removed. The plating 423, 425, 427 on the finger 421 may be connected (e.g., electrically connected) to circuitry/one or more electrical components of the daughterboard PCB 420. Again, while not shown, finger 421 may also include plating on one or more of the other two surfaces as discussed above (e.g., surfaces similar to surfaces 332a and/or 332b of FIG. 3) (i.e., include plating on four to five surfaces). One will recognize that the plating on one or more surfaces of a given finger may or may not be electrically connected to each other.

The motherboard PCB 410 may include one or more holes 412. For example, the motherboard PCB 410 may include a plurality of holes that includes the hole 412. The hole 412 may extend through the motherboard PCB from the first surface 414 to the second opposing surface 416. The hole 412 may be plated. For example, the hole 412 may include plating 418. The hole 412 (and other holes of the motherboard PCB) may be drilled or punched when the fingers of the daughterboard PCB are routed (as discussed above) and may be plated when surfaces of the daughterboard PCB (e.g., surfaces similar to surfaces 332a and 332b of daughterboard PCB 300) are plated for example. The plating 418 may surround and cover the inside/inner drilled/punched out surface of hole 412. The plating 418 may extend onto the upper surface 414 and/or the lower surface 416 of the motherboard PCB 410 thereby forming plating 451 (e.g., thereby forming an annular ring) on the upper surface 414 surrounding the hole 412 and/or forming plating 452 (e.g., thereby forming an annular ring) on the lower surface 416 surrounding the hole. The plating 418 on the hole 412 (and surrounding the hole on the upper and lower surfaces of motherboard 410) may be connected (e.g., electrically connected) to circuitry/one or more electrical components of the motherboard PCB 410. The hole 412 may be configured to receive the finger 421 such that at least a portion of each of the four surfaces of the finger (including, for example, surfaces 422a and 424a) are adjacent to the inner surface of the hole. The finger 421 may be configured to have a height (as similarly discussed with respect to distance D1 of FIG. 3) so as to extend into the hole at least to surface 416 and/or through the hole 412 extending pass surface 416 as shown in FIG. 4. For example, the finger 421 may extend through the hole 412 such that the plating 427 on the lower surface 426 of the finger 421 extends a distance D2 from the lower surface 416 of the motherboard PCB 410. The distance D2 may be configured such that an electrical connection and a structural connection between the daughterboard PCB 420 and the motherboard PCB 410 can be maintained. As shown, the plating along finger 421 (e.g., plating 423 and 425) may be of a length such that when the finger is inserted into hole 412, the plating extends above/beyond surface 414 of the motherboard PCB 410 (e.g., a distance approximately D2 from the upper surface 414 of the motherboard PCB 410) and extends below/beyond surface 416 of the motherboard PCB 410 (e.g., a distance approximately D2 from the lower surface 416 of the motherboard PCB 410), in addition to extending along the length of the plated hole 412 (i.e., along plating 418). One will recognize that the plating 423 and 425 of the finger that extends above/beyond surface 414 of the motherboard PCB 410 may extend beyond the surfaces 422a and 424b of the finger and onto the surfaces 422 and 424 of the PCB 420. In general, the cross-sectional thickness of finger 421 may dictate the size/diameter of the hole 412. In turn, the size/diameter of the hole, the hole fill ratio being soldered, and the soldering process being used (e.g., wave soldering vs Fountain soldering), may dictate the size of the plating 451 and 452 (e.g., the size of the annular ring) on each surface of the motherboard 410 and the length by which the plating 423 and 425 extends along the finger 421.

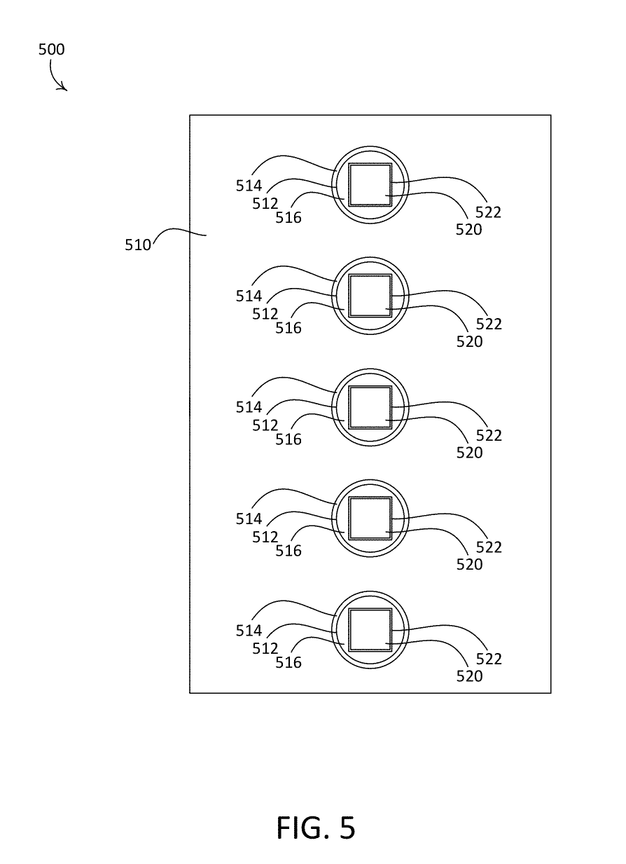

When the finger 421 is inserted into the hole 412, there may be a gap 440 between the plating 423, 425 on the finger 421 and the plating 418 on the hole 412, for example. The gap 440 may extend around the circumference of finger 421 and hole 412 (the gap may vary in horizontal length around this circumference, for example, as shown in FIG. 5). Solder may be inserted into the gap 440 to create a solder joint 430. The solder of the solder joint 430 may be fountain selective solder (FSS), wave solder, selective solder, hand solder, and/or another solder type. The solder joint 430 may extend 360 degrees around the circumference of the finger 421 such that the solder joint 430 fills the gap 440. The solder joint may physically contact/connect to the plating that may be on any of the four surfaces or sides (e.g., surfaces similar to surfaces 332a, 332b, and 332d etc. of FIG. 3) of the finger 421. The solder joint 430 may extend beyond and onto the upper surface 414 of the motherboard PCB 410. For example, the solder of the solder joint 430 may connect to the plating 418 of the hole 412 that extends onto the upper surface 414 of the motherboard PCB 410. The solder joint 430 may extend beyond and onto the lower surface 416 of the motherboard PCB 410. For example, the solder of the solder joint 430 may connect to the plating 418 of the hole 412 that extends onto the lower surface 416 of the motherboard PCB 410. The solder joint may also extend beyond the upper surface 414 and the lower surface 416 of the motherboard along at least a portion of the plating 423 and plating 425 of finger 421 that extend beyond the surfaces of the motherboard. In this fashion, the solder joint may completely fill hole 412.

The solder joint 430 may be configured to electrically connect the daughterboard PCB 420 and the motherboard PCB 410. The solder joint 430 may be configured such that the plating 423, 425, 427 on the finger 421 is electrically connected to the plating 418 on the hole 412, for example. The solder joint 430, the plating 423, 425, 427 on the finger, and the plating 418 on the hole 412 may be configured to electrically connect the circuitry/one or more electrical components of the daughterboard PCB 420 (that may be electrically connected to the plating 418) with the circuitry/one or more electrical components of the motherboard PCB 410 (that may be electrically connected to the plating 423, 425, 427 on the finger). The solder joint 430 may be configured to secure the daughterboard PCB 420 to the motherboard PCB 410. The solder joint 430 may be configured to structurally support the daughterboard PCB 420 within the motherboard PCB 410. For example, the solder joint 430 may secure the finger 421 within the hole 412. The solder joint 430 may be configured to provide redundant current paths between the daughterboard PCB 420 and the motherboard PCB 410. The solder joint 430 may be configured as a standard IPC through-hole joint. That is, the plated finger may act as a through-hole solder component wherein the solder joint 430 may have 360 degrees of solder connection. Assuming daughterboard 420 includes a plurality of fingers and motherboard 410 includes a plurality of respective holes, each of the fingers of the daughterboard PCB and respective holes of the motherboard PCB may be similarly configured and electrically connected via solder joints for example, as similarly discussed above for finger 421 and hole 412. In addition, any one or more of the fingers and holes, when soldered together, may or may not be configured to electrically connect circuitry/one or more electrical components of the daughterboard PCB 420 with circuitry/one or more electrical components of the motherboard PCB 410. In addition, assuming the daughterboard PCB 420 includes a tab(s) and the motherboard includes a respective slot(s) as described with respect to FIG. 2 for tab 224 and slot 216 for example, the tab of the daughterboard PCB and the slot of the motherboard PCB may be similarly configured with plating and be electrically connected via a solder joint for example, as similarly discussed above for finger 421 and hole 412. According to another example, assuming the daughterboard PCB 420 includes a tab(s) and the motherboard includes a respective slot(s), the tab and slot may not be plated and if plated, may not be soldered together. Rather, the tab and slot may be configured such that the tab fits snuggly with the slot (e.g., such that one or more sides of the tab contact one or more areas of the inner surface of the slot). Similarly, assuming a tab and slot of the daughterboard PCB and motherboard PCB are plated and soldered together, the tab and slot may or may not be configured to electrically connect circuitry/one or more electrical components of the daughterboard PCB 420 with circuitry/one or more electrical components of the motherboard PCB 410. Other variations are possible.

FIG. 5 is a bottom view of an example PCB assembly 500. As an example, assuming the motherboard PCB 210 and a daughterboard PCB 220 of FIG. 2 are plated and connected, FIG. 5. may be the bottom view along view Z as shown in FIG. 2 and along view W as shown in FIG. 4, for example. The PCB assembly 500 may include a motherboard PCB 510 (e.g., which may be similar to motherboard PCB 210 and motherboard PCB 410 as shown in FIGS. 2 and 4 respectively). A bottom or lower side or surface, for example, of motherboard PCB 510 is shown in FIG. 5, which surface may be similar to surface 213 of motherboard PCB 210 and surface 416 of motherboard PCB 410. The PCB assembly 500 may also include a daughterboard PCB that includes a plurality of fingers 520 (e.g., the daughterboard PCB may be similar to daughterboard PCBs 220, 300, 420 as shown in FIGS. 2-4 respectively). FIG. 5. shows a bottom or lower surface of fingers 520 of the daughterboard PCB (e.g., a surface similar to surface 332c of daughterboard 300 or surface 426 of daughterboard 420). The motherboard PCB 510 may include one or more holes 512. The holes 512 may be plated. For example, each of the holes 512 may include plating 514 that surrounds the inner surface of the hole and extends onto the lower surface of the motherboard 510 as shown in FIG. 5 and as similarly described with respect to FIG. 4 for example (e.g., as plating 452). The fingers 520 may have a rectangular and/or square cross section, for example. The fingers 520 may be plated. For example, the fingers 520 may include plating 522 that covers the four sides of the fingers 520 that define the rectangular cross section, for example, as similarly described herein. There may also be plating on the lower/bottom surface of each finger as similarly described herein.

Each of the holes 512 may be configured to receive a respective finger of the one or more fingers 520 of the daughterboard PCB as shown. When the fingers 520 of the daughterboard PCB are inserted through the holes 512 of the motherboard PCB 510, a gap 516 may be formed between the plating 522 on each of the fingers 520 and the plating 514 of the respective hole of the holes 512. The fingers 520 may be aligned with the holes 512 such that the gap 516 is substantially equivalent on each side of the fingers 520 that define the rectangular and/or square cross section. Solder may be inserted into each gap 516 to create respective solder joints. The respective solder joints may extend 360 degrees around the circumference of each finger 521 such that the respective solder joints fill the gaps 516 and connect (e.g., electrically connect) respective fingers and holes. The solder joints may extend beyond and onto the lower surface of the motherboard PCB 510. For example, the solder of the solder joints may connect to the plating 514 of the hole 512 that extends onto the lower surface of the motherboard PCB 510 as similarly described herein.

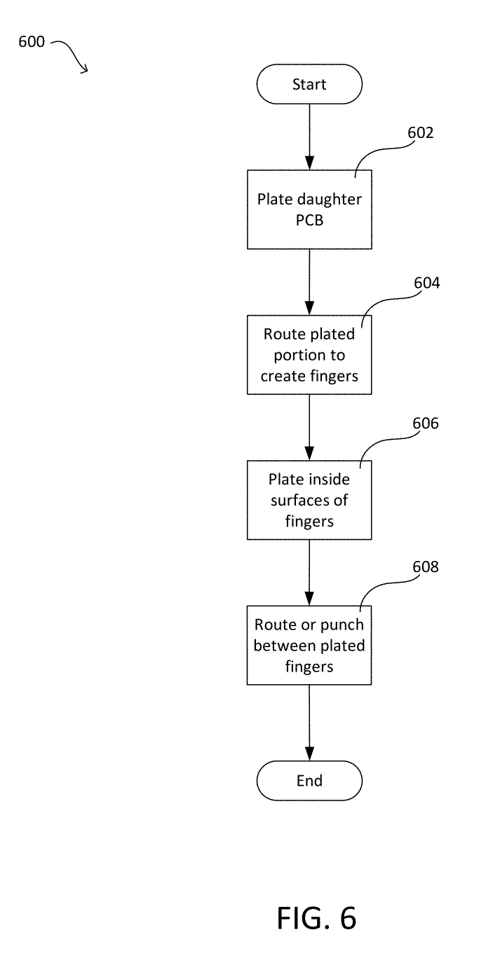

A PCB may be assembled as described herein according to the example method 600 shown in FIG. 6. At step 602, at least part of a lower portion or area of a daughterboard PCB may be plated, for example. This may include plating a side(s) or surface(s) of the PCB or etching a PCB stackup such that a bottom and/or a top side (which may also be referred to as a rear and/or a front side or surface) of the PCB may include a plated surface. At step 604, one or more fingers may be created from the plated lower portion of the daughterboard PCB. One or more tabs may be created from the plated lower portion of the daughterboard PCB. For example, the plated lower portion of the daughterboard PCB may be routed or milled to create the finger(s) and/or the tab(s). Each of the fingers may have, for example, four sides or surfaces including a front surface, an opposing rear surface, and two inside surfaces (each opposing the other and perpendicular to the front and rear surfaces, for example). These four surfaces may be similar to surface 332d of the daughterboard PCB 300, the opposing surface to surface 332d that is along the rear side or surface 334 of the daughterboard PCB 300, and the two opposing inside surfaces 332a and 332b of the daughterboard PCB 300 as shown in FIG. 3 Each finger may also include a lower surface that is perpendicular to each of the front surface and rear surface, for example. The lower surface may be rectangular and/or square in shape. This lower surface may be similar to surface 332c of daughterboard 300. The front and rear surfaces of each finger may be plated as a result of the plating at step 602, for example. The front and rear surface plating of each finger may be similar to plating 312 along surface 332d and the plating on the rear surface opposing surface 332d of PCB 300, for example, and/or may be similar to plating 423 on the first surface 422a of PCB 420 and plating 425 on the second surface 424a of PCB 420, for example. At step 606, the inside surfaces (e.g., surfaces similar to surfaces 332a and 332b of daughterboard PCB 300) of each of the fingers may be plated such that each of the fingers has plating on the four surfaces (e.g., the front surface, the opposing rear surface, and the two inside surfaces). The lower surface of each finger may also be plated, such that five surfaces are plated. At step 608, the daughterboard PCB (e.g., a lower edge of the daughterboard PCB, such as an edge similar to edge 223 of PCB 220 or edge 313 of PDB 300) may be routed or milled between the fingers. Routing the daughterboard PCB between the fingers may remove material (e.g., that may include excess plating) from the daughterboard PCB such that the lower edge of the daughterboard PCB between respective/adjacent plated fingers is concave, for example (as similarly shown for concave sections 226 of daughterboard PCB 220 and concave sections 316 of daughterboard PCB 300 for example). The daughterboard PCB (e.g., the lower edge of the daughterboard PCB) may be routed, milled, drilled, or punched on either side of the fingers. Routing the daughterboard PCB in areas on either side of the fingers may remove material (e.g., that may include excess plating) from the daughterboard PCB in these areas such that the lower edge of the daughterboard PCB in these areas on either side of respective plated fingers is concave.

A motherboard PCB may define one or more holes. The holes may be plated as described herein. The plated fingers of the daughterboard PCB may be inserted into respective holes of the motherboard PCB. Solder may be applied between each of the plated fingers and its respective plated hole. The solder for each respective plated finger and respective plated hole may fill a gap defined by the respective plated finger and the respective plated hole. For example, one or more solder joints may be created for the plated fingers. Each solder joint may extend around (e.g., 360 degrees around) a respective plated finger and physically (and thus electrically) contact the plating on each of the four surfaces of the finger (e.g., physically contact each of the surface other than the lower surface). Each solder joint may extend above and/or below and onto the upper and/or lower surfaces of the motherboard PCB as described herein.

While the fingers 222, 310, 421, 521 as shown and described herein have rectangular and/or square cross sections, the fingers 222, 310, 421, 521 may have cross sections of a different shape. For example, the fingers 222, 310, 421, 521 may be in the shape of a trapezoid, triangle, circle, oval, or other suitable shape. While the holes 214, 412, 512 are shown and described herein as circular, the holes 214, 412, 512 may have cross sections of a different shape. For example, the holes 214, 412, 512 may be in the shape of a rectangle, triangle, oval, or other suitable shape. While sections 226 and 316 are describe herein as being concave in shape, other suitable shapes may be used that result in, for example, excess plating between adjacent fingers from being removed. One will recognize that different finger/hole combinations of a given motherboard/daughterboard PCB combination may be different. One will also recognize that a given motherboard PCB may have attached thereto multiple daughterboard PCBs configured/connected in the fashion described herein.

While this disclosure has been described in terms of certain embodiments and generally associated methods, alterations and permutations of the embodiments and methods will be apparent to those skilled in the art. Accordingly, the above description of example embodiments does not constrain this disclosure. Other changes, substitutions, and alterations are also possible without departing from the spirit and scope of this disclosure.

What is claimed is:

1. A printed circuit board (PCB) assembly comprising:
a first PCB comprising:
a first surface and an opposing second surface, and
a hole that extends through the first PCB from the first surface to the second surface, wherein:
the hole comprises an inner surface, and
the inner surface of the hole comprises plating;
a second PCB comprising:
a first surface, an opposing second surface, and an edge that is perpendicular to the first and second surfaces of the second PCB, and
a finger that extends from the edge of the second PCB, wherein
the finger comprises four surfaces,
at least one of the four surfaces comprises plating, and
the hole of the first PCB has received therein the finger of the second PCB such that at least a portion of each of the four surfaces of the finger are adjacent to the inner surface of the hole and such that the edge of the second PCB is adjacent to the first surface of the first PCB; and
a solder joint that electrically connects the plating on the inner surface of the hole to the plating on the at least one surface of the finger.

2. The PCB assembly of claim 1, wherein:
the first PCB further comprises a first electrical component electrically connected to the plating on the inner surface of the hole,
the second PCB comprises a second electrical component electrically connected to the plating on the on the at least one surface of the finger, and
the solder joint electrically connects the electrical component of the first PCB to the electrical component of the second PCB.

3. The PCB assembly of claim 2, wherein:
the four surfaces of the finger comprise plating, and
the solder joint extends 360 degrees around the four surfaces of the finger such that the solder joint physically contacts the plating on each of the four surfaces of the finger.

4. The PCB assembly of claim 2, wherein at least two of the four surfaces of the finger comprise plating, and wherein the solder joint electrically connects the plating on the inner surface of the hole to the plating on the at least two surfaces of the finger.

5. The PCB assembly of claim 4, wherein:
the four surfaces are configured such that the finger comprises a square or rectangular cross section, and
the at least two surfaces of the finger that comprise plating are opposing surfaces.

6. The PCB assembly of claim 4, wherein:
the finger of the second PCB extends along a length of the inner surface of the hole and further extends beyond the second surface of the first PCB, and
the plating on the at least two surfaces of the finger extends along the length of the inner surface of the hole, and further extends a distance beyond the first surface and a distance beyond the second surface of the of the first PCB.

7. The PCB assembly of claim 6, wherein the plating on the inner surface of the hole extends onto the first surface and onto the second surface of the first PCB.

8. The PCB assembly of claim 7, wherein the solder joint fills the hole, and extends onto and connects to the plating of the hole that extends onto the first surface and onto the second surface of the first PCB.

9. The PCB assembly of claim 8,
wherein the first PCB further comprises a second hole that extends through the first PCB from the first surface to the second surface, wherein:
the second hole comprises an inner surface, and
the inner surface of the second hole comprises plating;
wherein the second PCB further comprises a second finger that extends from the edge of the second PCB, wherein
the second finger comprises four surfaces,
at least one of the four surfaces of the second finger comprises plating, and
the second hole of the first PCB has received therein the second finger of the second PCB; and
wherein the PCB assembly further comprises a second solder joint that electrically connects the plating on the inner surface of the second hole to the plating on the at least one surface of the second finger.

10. The PCB assembly of claim 9, wherein the first surface of the first PCB is approximately perpendicular to the first surface of the second PCB.

11. The PCB assembly of claim 8, wherein:
the first PCB further comprises a slot that extends through the first PCB from the first surface to the second surface, and
the second PCB further comprises a tab that extends from the edge of the second PCB, wherein:
the first and second fingers each comprise a first length,
the tab comprises a second length, wherein the first and second lengths run parallel with the edge, and
the second length of the tab is longer than the first length of the first and second fingers, and
the slot of the first PCB has received therein the tab of the second PCB.

12. The PCB assembly of claim 11, wherein the tab of the second PCB and the slot of the second PCB are configured to prevent lean of the second PCB with respect to the first PCB.

13. The PCB assembly of claim 8, wherein the first and second fingers are spaced apart from one another and wherein the second PCB defines a section along the edge between the first and second fingers wherein the section is formed by removing a portion of the edge.

14. The PCB assembly of claim 8, wherein:
the finger further comprises a fifth surface that is perpendicular to each of the four surfaces, and
the fifth surface comprises plating that is electrically connected to the plating on the at least surfaces of the finger.

15. The PCB assembly of claim 8, wherein:
the first PCB comprises a motherboard, and
the second PCB comprises a daughterboard.

16. A printed circuit board (PCB) assembly comprising:
a first PCB having a plurality of plated holes; and
a second PCB having a plurality of plated fingers extending from an edge of the second PCB,
wherein each of the plurality of plated holes of the first PCB are configured to receive a respective plated finger of the second PCB; and
wherein each of the plurality of plated holes is configured to be electrically connected to the respective plated finger via a solder joint that extends 360 degrees around the respective plated finger.

17. The PCB assembly of claim 16, wherein each of the plurality of plated fingers has a rectangular cross section and is plated on four sides that define the rectangular cross section.

18. The PCB assembly of claim 17, wherein a lower surface of each of the plurality of plated fingers is plated.

19. The PCB assembly of claim 16, wherein each of the plurality of plated holes has plating on an inside surface, and wherein the plating on each of the plurality of plated holes extends onto a first surface of the first PCB and a second opposing surface of the first PCB.

20. The PCB assembly of claim 19, wherein each solder joint extends beyond the first surface and beyond the second surface of the first PCB.

21. The PCB assembly of claim 16, wherein each of the plurality of plated fingers is routed from an edge of the second PCB.

22. The PCB assembly of claim 16, wherein the second PCB comprises a tab that is configured to be received by a slot defined by the first PCB, and wherein the tab and the slot are configured to prevent lean of the second PCB with respect to the first PCB.

23. The PCB assembly of claim 16, wherein:
the first PCB further comprises a first electrical component electrically connected to a first plated hole of the plurality of plated holes,
the second PCB comprises a second electrical component electrically connected to a first plated finger of the plurality of plated fingers, wherein the first plated hole is configured to receive the first plated finger, and
wherein when the first plated hole is electrically connected to the first plated finger via a solder joint, the first electrical component is electrically connected to the second electrical component.

24. A method of connecting a second printed circuit board (PCB) to a first PCB, the method comprising:
plating a portion of opposing sides of the second PCB;
routing at least a portion of the plated portion of the second PCB to create a plurality of fingers,
wherein each of the plurality of fingers comprises a front surface, a rear surface, two inside surfaces, and a lower surface that is perpendicular to each of the front surface and the rear surface, and
wherein the front surface and the rear surface of each of the plurality of fingers comprises plating;
plating the inside surfaces and the lower surface of each of the plurality of fingers to form a plurality of plated fingers;
removing portions of the second PCB between each of the plurality of plated fingers;
inserting each of the plurality of plated fingers into a respective one of a plurality of plated holes in the first PCB; and
soldering each of the plurality of plated fingers and its respective plated hole.

25. The method of claim 24, wherein subsequent to soldering each of the plurality of plated fingers and its respective plated hole, the opposing sides of the second PCB are each approximately perpendicular to a side of the first PCB.

26. The method of claim 24, wherein removing portions of the second PCB between each of the plurality of plated fingers comprises routing or punching the second PCB between each of the plurality of plated fingers.

27. The method of claim 26, wherein routing or punching the second PCB between each of the plurality of fingers results in respective areas of the second PCB between each of the plurality of plated fingers having a curved shape.

28. The method of claim 24, wherein soldering each of the plurality of plated fingers and its respective plated hole comprises creating a respective solder joint for each of the plurality of plated fingers and its respective plated hole, wherein each respective solder joint extends 360 degrees around the respective plated finger.

29. The method of claim 28, further wherein each of the solder joints extends above and below sides of the first PCB.

30. The method of claim 24, further comprising:
routing the second PCB to create a tab; and
inserting the tab of the second PCB into a slot defined by the first PCB, wherein the tab and the slot are configured to prevent lean of the second PCB with respect to the first PCB.
